(19) United States
(12) Patent Application Publication
(10) Pub. No.: US 2008/0210986 A1
(43) Pub. Date: Sep. 4, 2008

(54) Global shutter pixel with charge storage region

(75) Inventor: Richard A. Mauritzson, Meridian, ID (US)

Correspondence Address: DICKSTEIN SHAPIRO LLP, 1825 EYE STREET, NW, WASHINGTON, DC, 20006, US

(73) Assignee: MICRON TECHNOLOGY, INC

(21) Appl. No.: 11/712,994

(22) Filed: Mar. 2, 2007

(51) Int. Cl. H01L 27/148; H01L 27/00

(52) U.S. Cl. 257/239; 438/60; 257/E21.001; 257/E27.15

(57) ABSTRACT

An imaging method, apparatus, and system having pixels that store charge from a photosensor in a storage diode are disclosed. Charge accumulated in the photosensor during an integration period is transferred to and stored in the storage diode prior to readout in a global shutter imager.

### FIELD OF THE INVENTION

Embodiments of the invention relate generally to imaging devices and more particularly to a global shutter pixel with a charge storage region.

### BACKGROUND

A CMOS imager circuit includes a focal plane array of pixels, each one of the pixels including a photosensor, for example, a photogate, photoconductor or a photodiode overlying a substrate for accumulating photo-generated charge in the underlying portion of the substrate. Each pixel has a readout circuit that includes at least an output field effect transistor formed in the substrate and a charge storage region formed on the substrate connected to the gate of an output transistor. The charge storage region may be constructed as a floating diffusion region. Each pixel may include at least one electronic device such as a transistor for transferring charge from the photosensor to the storage region and one device, also typically a transistor, for resetting the storage region to a predetermined charge level prior to charge transference.

In a CMOS imager, the active elements of a pixel perform the necessary functions of: (1) photon to charge conversion; (2) accumulation of image charge; (3) resetting the storage region to a known state; (4) transfer of charge to the storage region; (5) selection of a pixel for readout; and (6) output and amplification of a signal representing pixel charge. The charge at the storage region is typically converted to a pixel output voltage by a source follower output transistor.

CMOS imagers of the type discussed above are generally known as discussed, for example, in U.S. Pat. No. 6,140,630, U.S. Pat. No. 6,376,868, U.S. Pat. No. 6,310,366, U.S. Pat. No. 6,326,652, U.S. Pat. No. 6,204,524 and U.S. Pat. No. 6,333,205, assigned to Micron Technology, Inc., which are hereby incorporated by reference in their entirety.

FIG. 1 illustrates a schematic view and FIG. 2 illustrates a top down view of a pixel 110 that may be used in a pixel array to implement a global shutter operation of an imager. The pixel 110 contains a photosensor 112, e.g. a pinned photodiode, a transfer transistor 114 having a gate 114′, a storage transistor 124 having a gate 124′, a floating diffusion region FD to collect charge transferred from the photosensor 112 via gate 124′ and gate 114′, a reset transistor 116 having a gate 116′, row select transistor 120 having a gate 120′, and a source follower output transistor 118 having a gate 118′. FIG. 1 also shows an anti-blooming transistor 125 having a gate 125′, which may be used to drain away excess charge from the photosensor 112 when an anti-blooming control signal AB is applied to the anti-blooming transistor gate 125′. The anti-blooming transistor 125 may also be used as an alternative method to reset the photosensor 112. Without the anti-blooming transistor 125, the pixel 110 is a five transistor (5T) pixel. If the anti-blooming transistor 125 is used, the pixel 110 is a six transistor (6T) pixel.

The reset transistor 116 is connected between the floating diffusion region FD, acting as one source/drain region, and an array pixel supply voltage Vaa, connected to another source/drain region. A reset control signal RST is used to activate the reset transistor gate 116′, which resets the floating diffusion region FD to the array pixel supply voltage Vaa level as is known in the art.

In a global shutter operation, the start of a charge integration period occurs at the same time for all pixels of a pixel array. During the integration period, each photosensor 112 accumulates charge representative of light impinging on the photosensor 112. At the end of the charge integration period, the storage transistor gate 124′ is activated when a storage gate control signal SG is applied to a storage gate control line 124a, to transfer the charge collected by the photosensor 112 to the storage transistor gate 124′, where the charge is held in an n-type doped channel region 124b located directly under the storage transistor gate 124′. When the charge stored by the storage transistor gate 124′ of a particular pixel is ready to be read out, the pixel's transfer transistor gate 114′ is activated by the TX control signal allowing a transfer of the stored charge from the channel region 124b, which serves as one source/drain region of the transfer transistor 114, to the floating diffusion region FD, which serves as the other source/drain region of the transfer transistor 114.

The source follower transistor gate 118′ is connected to the floating diffusion region FD and the source follower transistor 118 has one source/drain region connected to the array pixel supply voltage Vaa and another source/drain region connected to the row select transistor 120. The source follower transistor 118 converts the charge stored at the floating diffusion region FD into an electrical output voltage signal Vout, which the row select transistor under control of gate 120′ transfers onto a column line 122. The row select transistor gate 120′ is controllable by a row select signal SEL for selectively connecting the source follower transistor output voltage signal Vout to column line 122.

In a conventional pixel used in a global shutter operation, all or substantially all of the n-type doped channel region 124b is located directly under the storage transistor gate 124′. Storing the charge under the storage transistor gate 124′ in a global shutter operation, however, may cause an increase in dark current (i.e., current generated by a process other than light impinging on the photosensor 112) due to interaction with surface states under the storage transistor gate 124′. Dark current is disadvantageous because it may cause the electrical output voltage signal Vout to be improperly increased. Therefore, there is a need and desire for an improved technique for storing charge in a pixel used for a global shutter operation that mitigates against the aforementioned shortcomings of the conventional shutter gate pixel.

### BRIEF DESCRIPTION OF THE DRAWINGS

FIG. 1 illustrates a schematic view of a conventional global shutter pixel for use in a CMOS imager.

FIG. 2 illustrates a top down view of the pixel of FIG. 1.

FIG. 3 illustrates a pixel array suitable for use with any of the embodiments described herein.

FIG. 4 illustrates a schematic view of a pixel constructed in accordance with an embodiment for use in a CMOS imager.

FIG. 5 illustrates a top view of the pixel of FIG. 4.

FIG. 6 illustrates a cross-section view of the pixel of FIG. 4.

FIG. 7 illustrates a potential diagram for a pixel of an embodiment.

FIG. 8 illustrates a system suitable for use with any of the embodiments described herein.

FIG. 9 illustrates a cross-section view of a pixel in a stage of manufacture.

FIG. 10 illustrates a cross-section view of the pixel of FIG. 9 in a subsequent stage of manufacture.

FIG. 11 illustrates a cross-section view of the pixel of FIG. 10 in a subsequent stage of manufacture.

FIG. 12 illustrates a cross-section view of the pixel of FIG. 11 in a subsequent stage of manufacture.

FIG. 13 illustrates a cross-section view of the pixel of FIG. 12 in a subsequent stage of manufacture.

### DETAILED DESCRIPTION

In the following detailed description, reference is made to the accompanying drawings, which are a part of the specification, and in which is shown by way of illustration various embodiments of the invention and how they may be practiced. These embodiments are described in sufficient detail to enable those skilled in the art to make and use them. It is to be understood that other embodiments may be utilized, and that structural, logical, and electrical changes, as well as changes in the materials used, may be made.

The term “pixel” refers to a photo-element unit cell containing a photo-conversion device or photosensor and transistors for processing an electrical signal from electromagnetic radiation sensed by the photo-conversion device. The pixels discussed herein are illustrated and described as six transistor (6T) pixel circuits for the sake of example only. It should be understood that the embodiments are not limited to a six transistor (6T) pixel, but may be used with other pixel arrangements having fewer or more than six transistors. Although the embodiments are described herein with reference to the architecture and fabrication of one pixel, it should be understood that this is representative of a plurality of pixels in an array of an imager device. In addition, although the embodiments are described below with reference to a CMOS imager, they have applicability to other solid state imaging devices having pixels. The following detailed description is, therefore, not to be taken in a limiting sense.

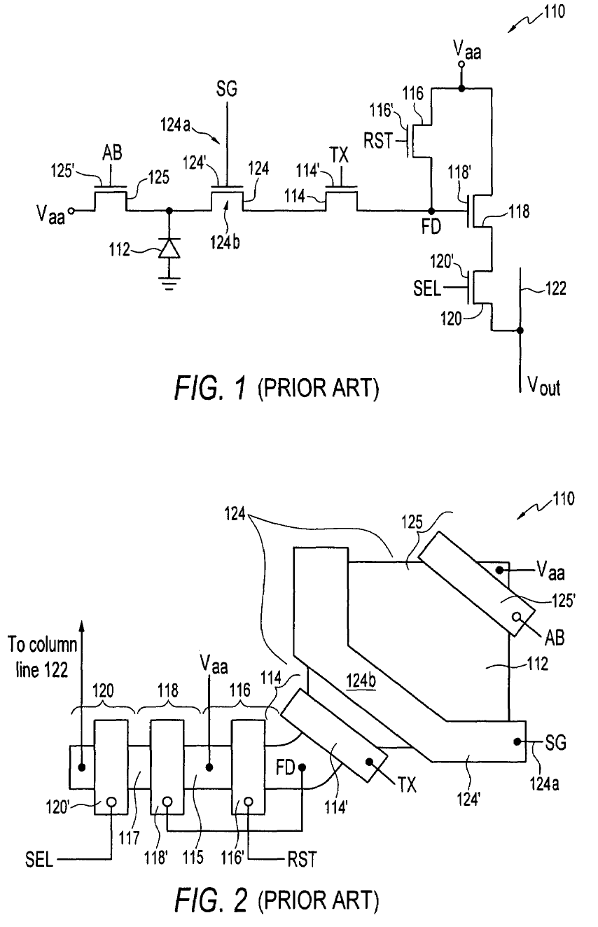

Embodiments disclosed herein provide an imager with reduced dark current by using a storage diode as a storage node to replace the storage gate used in the prior art pixel (FIG. 1). The storage diode reduces the effects of dark current due to less interaction between the storage region and the substrate surface.

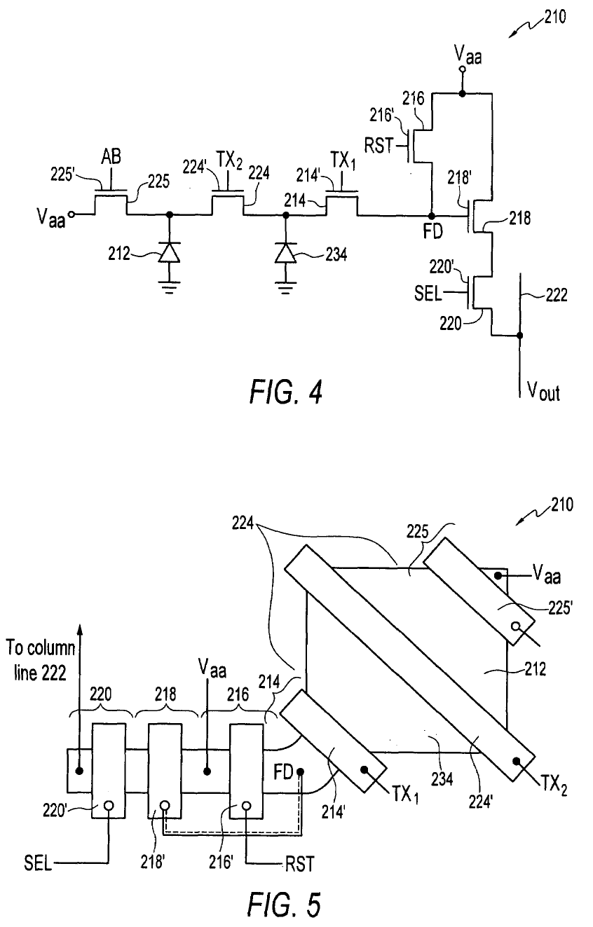

A pixel 210 according to an embodiment is illustrated in FIGS. 4, 5, and 6. The illustrated pixel 210 contains a pinned photodiode photosensor 212, a first transfer transistor 214 having a gate 214′, a floating diffusion region FD, a reset transistor 216 having a gate 216′, row select transistor 220 having a gate 220′, a source follower output transistor 218 having a gate 218′, and an optional anti-blooming transistor 225 having a gate 225′. The pixel 210 also includes a second transfer transistor 224 having a gate 224′ and a storage diode 234 arranged between the first transfer gate 214′ and the photosensor 212. The second transfer transistor 224 is arranged so that its source is coupled to the photosensor 212 and its drain is coupled to the storage diode 234. The first transfer transistor 214 is arranged so that its source is coupled to the storage diode 234 and its drain is coupled to the floating diffusion region FD.

The reset transistor 216 is connected between the floating diffusion region FD and an array pixel supply voltage Vaa. A reset control signal RST is used to activate the reset transistor gate 216′, which resets the floating diffusion region FD to the array pixel supply voltage Vaa level.

At the end of a charge integration period, the second transfer gate 224′ is activated by a control signal TX2 to transfer the charge collected by the pinned photodiode photosensor 112 to the storage diode 234, where the charge is held until it is time to read out the charge. A light blocking layer 242, such as a metal layer, is arranged over the storage diode 234 to prevent the storage diode 234 from generating charge due to incident light. When the charge stored by the storage diode 234 of a particular pixel 210 is ready to be read out, the first transfer gate 214 is activated to transfer the charge to the floating diffusion region FD.

The source follower transistor gate 218′ is connected to the floating diffusion region FD and the source follower transistor 218 is connected between the array pixel supply voltage Vaa and the row select transistor 220. The source follower transistor 218 converts the charge stored at the floating diffusion region FD into an electrical output voltage signal Vout. The row select transistor gate 220′ is controllable by a row select signal SEL for selectively connecting the output voltage signal Vout to column line 222.

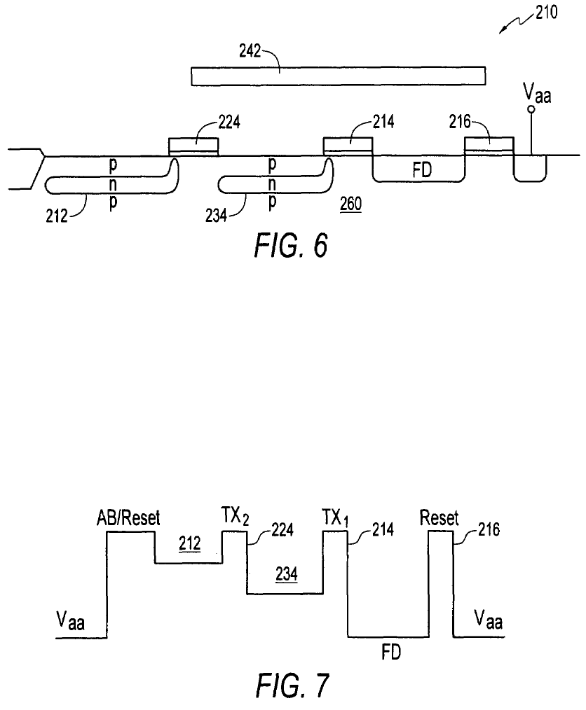

FIG. 6 shows a cross-section of a pixel cell in an embodiment in which the pixels 210 are formed in a p-type substrate or p-type epitaxial layer 260. The storage diode 234 and the pinned photodiode photosensor 212 are formed by implanting an n-type dopant in the p-type substrate or epitaxial layer 260 so that the storage diode 234 and the pinned photodiode photosensor 212 both have a p-n-p structure. A light blocking layer 242, such as a metal layer, is arranged over the storage diode 234 to prevent the storage diode 234 from generating charge due to incident light.

FIG. 6 shows an embodiment in which the storage diode 234 is located laterally or substantially laterally of the second transfer transistor gate 224′ and located laterally or substantially laterally of the first transfer transistor gate 214′. By having a p-type layer at the substrate surface over the storage diode 234 (i.e. burying the storage diode 234), and by reducing the portion of the storage diode 234 that is located under the second transfer transistor gate 224′ and/or the first transfer transistor gate 214′, the effects of dark current due to interaction between the storage diode 234 and the substrate surface may be reduced.

In one embodiment, a substantial portion of the storage diode 234 is not located directly under the second transfer transistor gate 224′. In an alternate embodiment, no portion of the storage diode 234 is located directly under the second transfer transistor gate 224′. In another alternate embodiment, less than fifty percent of the storage diode 234 is located directly under the second transfer transistor gate 224′. In another alternate embodiment, only an edge of the storage diode 234 is located directly under the second transfer transistor gate 224′ so that the edge of the storage diode 234 located directly under the second transfer transistor gate 224′ acts as a source/drain of the second transfer transistor 224.

Similarly, in the embodiment shown in FIG. 6, a substantial portion of the storage diode 234 is not located directly under the first transfer transistor gate 214′. In an alternate embodiment, no portion of the storage diode 234 is located directly under the first transfer transistor gate 214′. In another alternate embodiment, less than fifty percent of the storage diode 234 is located directly under the first transfer transistor gate 214′. In another alternate embodiment, only an edge of the storage diode 234 is located directly under the first transfer transistor gate 214′ so that the edge of the storage diode 234 located directly under the first transfer transistor gate 214′ acts as a source/drain of the first transfer transistor 214.

FIG. 7 illustrates a potential diagram associated with an operation of an embodiment of the pixel 210. As FIG. 7 illustrates, the pinned potential of the storage diode 234 should be greater than the pinned potential of the photosensor 212 and the capacitance of the storage diode sufficient so that all of the charge from photosensor 212 will be transferred to the storage diode 234 when the second transfer gate 224′ is activated by the control signal TX2. Similarly, the charge storage potential of the floating diffusion region FD should be greater than that of the storage diode 234 and capacitance sufficient so that all of the charge will be transferred to the floating diffusion region FD when the first transfer transistor gate 214′ is activated by the control signal TX1. The charge storage potential of the various regions may be modified by increasing or decreasing the doping concentration. For example, the n-type doped regions of the photosensor 212 and storage diode 234 may have a concentration in the range of about 5e16 cm⁻³ to about 1e18 cm⁻³.

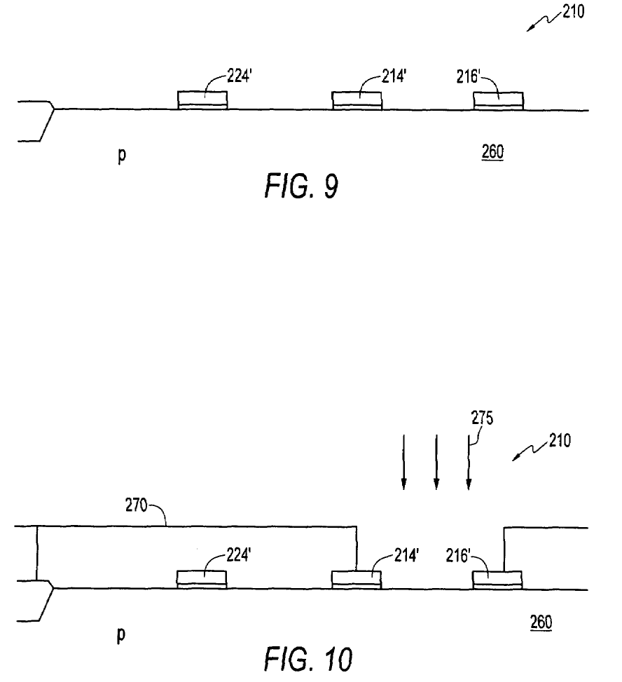

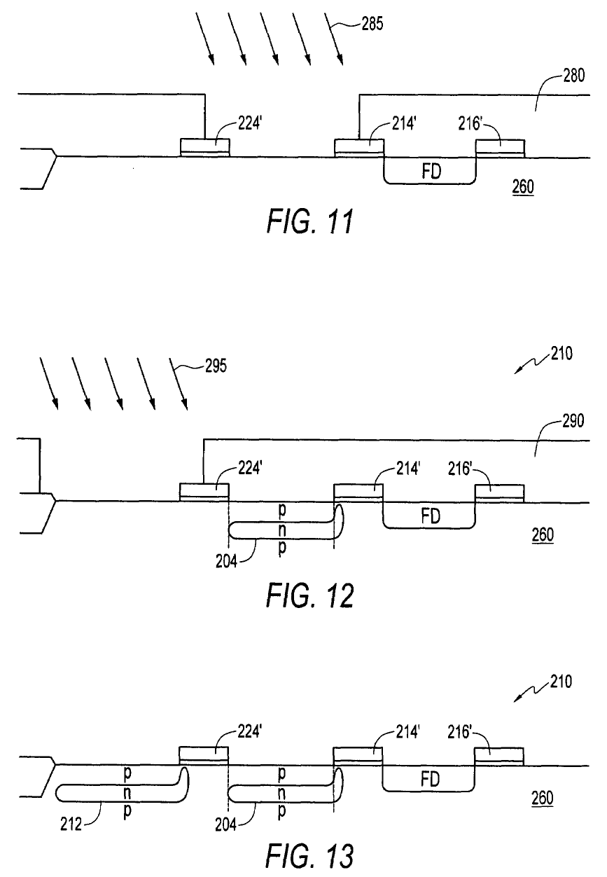

One embodiment includes a method of making the imaging device described above by forming the photosensor 212 and the storage diode 234 by implanting an n-type region in a p-type substrate or p-type epitaxial layer 260. As shown in FIG. 9, the first transfer transistor gate 214′, the second transfer transistor gate 224′, and the reset transistor gate 216′ are be formed on the substrate 260 by methods known in the art. As shown in FIG. 10, the floating diffusion region FD may be formed by implanting an n-type region in the substrate 260 using an n-type dopant implantation 275 and a photoresist layer 270. As shown in FIG. 11, the storage diode 234 may be formed by implanting an n-type region in the substrate 260 using an n-type dopant implantation 285 and a photoresist layer 280. As shown in FIG. 12, the photosensor 212 (FIG. 13) may be formed by implanting an n-type region in the substrate 260 using an n-type dopant implantation 295 and a photoresist layer 290. Optionally, a p-type dopant implantation (not shown) may be performed to implant an enhanced p-type region over the n-type region of the photosensor 212 and/or over the n-type region of the storage diode 234. The dopant implantations 275, 285, 295 may be applied perpendicularly or at an angle to the substrate 260. Additionally, the photosensor 212, the storage diode 234, and the floating diffusion region FD may be formed in any order.

The storage diode 234 may be doped to a concentration such that the storage diode 234 has a greater pinned potential than the pinned potential of the photosensor 212, but less than the reset potential of the floating diffusion region FD. The light blocking layer may be formed over the storage diode 234 and the floating diffusion region FD.

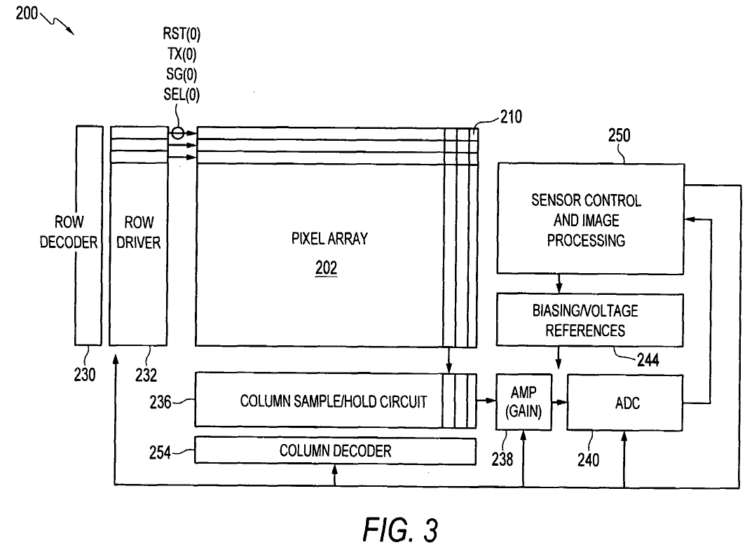

FIG. 3 illustrates a CMOS imager 200 that may incorporate the disclosed embodiment. The illustrated imager 200 includes a pixel array 202 comprising a plurality of pixels 210 arranged in a predetermined number of rows and columns. In operation, the pixels 210 of each row in the array 202 are all turned on at the same time by a row select line e.g., SEL(0) and the pixels 210 of each column are selectively output onto a column line 222 (FIG. 4). A plurality of row and column lines are provided for the entire array 202. The row lines e.g., SEL(0) are selectively activated by row decoder 230 and driver circuitry 232 in response to an applied row address. Column select lines (not shown) are selectively activated in response to an applied column address by column circuitry that includes column decoder 254. Thus, row and column addresses are provided for each pixel 210. The CMOS imager 200 is operated by a sensor control and image processing circuit 250, which controls the row and column circuitry for selecting the appropriate row and column lines for pixel readout.

Each column is connected to sampling capacitors and switches in the sample and hold circuitry 236. A pixel reset signal Vrst, which is taken after the floating diffusion region FD is reset by the reset transistor, and a pixel image signal Vsig, which is taken after charge is transferred by transfer gate 214 to the floating diffusion region FD, for selected pixels are sampled and held by the sample and hold circuitry 236. A differential signal (Vrst-Vsig) is produced for each readout pixel by the differential amplifier 238 (AMP), which applies a gain to the signal received from the sample and hold circuitry 236. The differential signal is digitized by an analog-to-digital converter 240 (ADC). The analog-to-digital converter 240 supplies the digitized pixel signals to the sensor control and image processing circuit 250, which among other things, forms a digital image output. The imager also contains biasing/voltage reference circuitry 244.

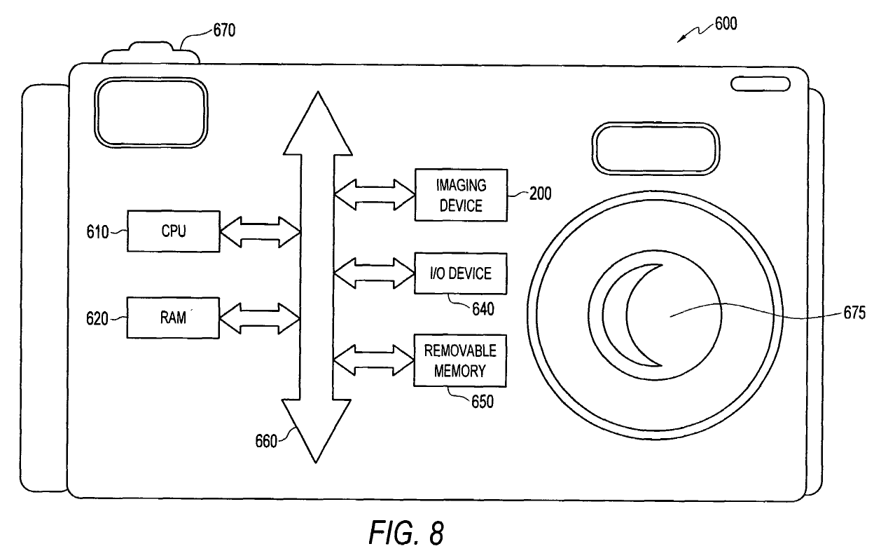

FIG. 8 shows a processor system 600, for example, a digital camera system, which includes an imaging device 200 constructed to include a pixel array 202 (FIG. 7) arranged and operated in accordance with an embodiment described herein. The processor system 600 is an example of a system having digital circuits that could include imaging devices. Without being limiting, in addition to a digital camera system, such a system could include a computer system, scanner, machine vision system, vehicle navigation system, video phone, surveillance system, auto focus system, star tracker system, motion detection system, image stabilization system, and other processing systems employing an imaging device 200.

System 600, for example a camera system, generally comprises a central processing unit (CPU) 610, such as a microprocessor, that communicates with an input/output (I/O) device 640 over a bus 660. Imaging device 200 also communicates with the CPU 610 over the bus 660. The system 600 also includes random access memory (RAM) 620, and can include removable memory 650, such as flash memory, which also communicate with the CPU 610 over the bus 660. Imaging device 200 may be combined with a processor, such as a CPU 610, digital signal processor, or microprocessor, in a single integrated circuit. In a camera application, a shutter release button 670 is used to operate a mechanical or electronic shutter to allow image light which passes through a lens 675 to be captured by the imaging device 200.

The processes and devices described above illustrate preferred methods and typical devices of many that could be used and produced. The above description and drawings illustrate embodiments, which achieve the objects, features, and advantages described herein. However, it is not intended that the embodiments be strictly limited to the described and illustrated embodiments.

What is claimed as new and desired to be protected by Letters Patent of the United States is:

1. An imaging device comprising:
an array of pixels, each pixel comprising:
a photosensor for accumulating charge;
a storage diode for storing charge;
a first gate for transferring charge from the photosensor to the storage diode;

2. The imaging device of claim 1, wherein a substantial portion of the storage diode is not located directly under the first gate.

3. The imaging device of claim 1, wherein none of the storage diode is located directly under the first gate.

4. The imaging device of claim 1, further comprising:
a floating diffusion region; and
a second gate for transferring charge from the storage diode to the floating diffusion region.

5. The imaging device of claim 4, wherein the storage diode has a greater pinned potential than a pinned potential of the photosensor and wherein the floating diffusion region has a greater potential than a pinned potential of the storage diode.

6. The imaging device of claim 1, wherein the storage diode has a greater pinned potential than a pinned potential of the photosensor.

7. The imaging device of claim 1, wherein the storage diode comprises an p-type region at a surface of a substrate and an n-type region below the p-type region.

8. The imaging device of claim 7, wherein said n-type region is found in a p-type substrate or p-type epitaxial layer.

9. The imaging device of claim 1, wherein each pixel further comprises:
a light blocking layer arranged over the storage diode.

10. An imaging pixel comprising:
a pinned photodiode for accumulating charge;
a light blocked pinned diode for receiving and storing charge from the photodiode,
a gate for transferring charge from the photodiode to the diode arranged substantially laterally of the diode;
a floating diffusion region for receiving charge from the diode; and
a transfer gate for transferring charge from the diode to the floating diffusion region.

11. The imaging pixel of claim 10, wherein the photodiode and diode have a P-N-P structure.

12. An imaging processing system comprising:
a processor; and
an imaging device communicating with the processor, the device comprising a plurality of pixels, each pixel comprising:
a photosensor for accumulating charge;
a storage diode for storing charge received from the photosensor;
a first transistor having a gate and a source coupled to the photosensor and a drain coupled to the storage diode;
a floating diffusion region; and
a second transistor having a gate and a source coupled to the storage diode and a drain coupled to the floating diffusion region,
wherein the storage diode has a greater pinned potential than the pinned potential of the photosensor and the floating diffusion region has a greater potential than the pinned potential of the storage diode, and
wherein a substantial portion of the storage diode is not located directly under the gate of the first transistor.

13. The imaging processing system of claim 12, wherein a substantial portion of the storage diode is not located directly under the gate of the second transistor.

14. The imaging processing system of claim 12, wherein the storage diode comprises a P-N-P diode.

15. The imaging processing system of claim 12, wherein each pixel further comprises:
a light blocking layer arranged at least over the storage diode.

16. The imaging processing system of claim 12, wherein the system is a digital camera.

17. The imaging processing system of claim 12, wherein the digital camera is operated using a global shutter.

18. A method of operating an imaging device, the imaging device comprising an array of pixels, each comprising a photosensor and storage diode, the method comprising the acts of:
for each pixel in a selected row of the array, transferring charge from the photosensor to the storage diode through a first gate after an integration period; and
for each pixel in the selected row, transferring charge from the storage diode to a floating diffusion region through a second gate and reading out the charge on the floating diffusion region
wherein a substantial portion of the storage diode is not located directly under the first gate.

19. The method of claim 18, wherein the charge stored on the storage diode is read out by a source follower transistor.

20. The method of claim 18, wherein, charge is transferred from the photosensor to the storage diode of each pixel of the array at the same time.

21. A method of making an imaging pixel comprising:
forming a photosensor for accumulating charge in a substrate;
forming a storage diode for storing charge in the substrate;
forming a first gate for transferring charge from the photosensor to the storage diode such that a substantial portion of the storage diode is not located directly under the first gate;
forming a floating diffusion region in the substrate; and
forming a second gate for transferring charge from the storage diode to the floating diffusion region.

22. The method of claim 21, wherein the storage diode is formed such that it has a greater pinned potential than a pinned potential of the photosensor and wherein the floating diffusion region is formed such that it has a greater potential than a pinned potential of the storage diode.

23. The method of claim 21, wherein forming the storage diode comprises forming a P-N-P diode.

24. The method of claim 21, further comprising forming a light blocking layer over the storage diode.
